(19) United States
(12) Patent Application Publication
(10) Pub. No.: US 2012/0006584 A1
(43) Pub. Date: Jan. 12, 2012

(54) WIRING BOARD AND LIQUID CRYSTAL DISPLAY DEVICE

(76) Inventors: Takashi Matsui, Osaka (JP); Motoji Shiota, Osaka (JP)

(21) Appl. No.: 12/673,440

(22) PCT Filed: Jul. 17, 2008
(86) PCT No.: PCT/JP08/62898

§ 371 Date: Feb. 12, 2010

(30) Foreign Application Priority Data
Aug. 10, 2007 (JP) 2007-210336

(51) Int. Cl. H05K 1/09; H05K 1/16; H05K 1/11

(52) U.S. Cl. 174/257; 174/261; 174/260

(57) ABSTRACT

A wiring board of the present invention (1) is arranged so that: pads (30) arranged in a plurality of rows include: first-row pads (30a) connected to first metal wires (10a) among metal wires (10); and second-row pads (30b) connected to second metal wires (10b) among the metal wires (10), the first metal wires (10a) being longer than the second metal wires (10b); and that each of the first connecting lines (10a) is formed so as to be separated from a corresponding one of the second-row pads (30b) by at least an insulating layer, and so as to extend not through a region between the corresponding second-row pad (30b) and a second-row pad (30b) adjacent to the corresponding second-row pad (30b), but through a region below the corresponding second-row pad (30b).

### TECHNICAL FIELD

The present invention relates to a wiring board. In particular, the present invention relates to a wiring board having pads arranged in a plurality of rows and to a liquid crystal display device including such a wiring board.

### BACKGROUND ART

Conventionally, there has been widely used a wiring board having pads arranged in a so-called plurality of rows for a narrow-pitch mounting.

In view of a demand for further reduction in size and weight of electronic devices including the wiring board, electronic components in each of such electronic devices are mounted at a higher density. Accordingly, the wiring board on which the electronic components are mounted are required to have a narrower pitch.

(Patent Literature 1)

In order to meet such a demand, various techniques have been suggested. Patent Literature 1, for example, discloses a technique to arrange a wiring board having pads provided in a plurality of rows. In the technique, the pads are provided in a layer different from a layer in which metal wires each extending between pads adjacent to each other are provided, and the pads have a dual structure. This is described below with reference to FIGS. 11 and 12. FIG. 11 is a view illustrating a configuration of the wiring board disclosed in Patent Literature 1. FIG. 12 is a cross-sectional view taken along line H-H of FIG. 11. The legends “FIRST ROW” and “SECOND ROW” in FIG. 11 indicate respective names of the plurality of rows of pads 105.

The wiring board 100 disclosed in Patent Literature 1, as illustrated in FIG. 11, is provided with metal wires 101 each provided so as to extend between pads 105 in the second row and so as to be connected to a corresponding pad 105 in the first row among all pads 105 arranged in the plurality of rows. The metal wire 101 is provided, as illustrated in FIG. 12, in a layer different from a layer in which the pads 105 in the second row are provided. More specifically, each pad 105 is provided in a layer above the metal wires 101 via an interlayer insulating layer 102 and which is thus different from the layer in which the metal wires 101 are provided.

Each pad 105 in the first and second rows is connected, via a through hole 103, to a corresponding metal wire 101 provided in the layer different from the layer in which the pad 105 is provided (see FIG. 11). Further, a pad 109 having an area larger than that of the pad 105 is provided, via an interlayer insulating layer 106, in a layer above the layer in which the pad 105 is provided. The pad 105 is connected to the pad 109 via a pad through hole 107 (see FIG. 11). In other words, the metal wire 101, the pad 105, and the pad 109 are formed in different layers, respectively. In other words, the metal wire 101 is formed in a first layer; the pad 105 is formed in a second layer; and the pad 109 is formed a third layer.

As described above, according to the wiring board 100 disclosed in Patent Literature 1, the metal wire 101 provided between second-row pads 105 is provided in the layer different from the respective layers of the pad 105 and the pad 109 (the interlayer insulating layer 102 is provided in a layer above the metal wire 101). This makes it possible to reduce a distance between adjacent second-row pads 109 to some extent.

(Patent Literature 2)

With reference to Patent Literature 2, the following describes an example case in which a wiring board on which electronic components are mounted is used as a display device substrate (a substrate for a display device).

Patent Literature 2 discloses a configuration in which pads are arranged on a liquid crystal panel in a plurality of rows in the same manner as in Patent Literature 1. The following description refers to FIGS. 19 to 22. FIG. 19 is a view illustrating a configuration of the liquid crystal panel disclosed in Patent Literature 2. FIG. 20 is a view illustrating a configuration of a bottom surface of a driving IC illustrated in FIG. 19. FIG. 21 is a view illustrating the liquid crystal panel on which the driving IC illustrated in FIG. 20 is mounted.

As illustrated in FIG. 19, the liquid crystal panel 300 disclosed in Patent Literature 2 has a driving IC 400 mounted directly thereon (chip on glass (COG) mounting). As illustrated in FIG. 20, the driving IC 400 that is COG-mounted on the liquid crystal panel 300 has a bottom surface having bumps 410 arranged in a plurality of rows. Further, as illustrated in FIG. 21, the liquid crystal panel 300 has a region in which the driving IC 400 is to be mounted. This region has electrode pads 320 that are formed therein so as to correspond to the respective bumps 410 formed on the bottom surface of the driving IC 400. Each of the electrode pads 320 is connected to an input line 310 which is a line connected to a pad.

### CITATION LIST

### Patent Literature 1

Japanese Patent Application Publication, Tokukaihei, No. 5-29377 A (Publication Date: Feb. 5, 1993)

### Patent Literature 2

Japanese Patent Application Publication, Tokukai, No. 2004-252466 A (Publication Date: Sep. 9, 2004)

### SUMMARY OF INVENTION

(Leak Failure)

The arrangement of Patent Literature 1 unfortunately tends to cause a problem of a leak failure between a pad 109 and a metal wire 101 when an electronic component such as a driving IC is mounted. The following description refers to FIG. 13. FIG. 13 is a view schematically illustrating a condition where an electric component is being mounted to a wiring board.

As illustrated in FIG. 13, when a bump 120 formed on a driving IC is joined to the wiring board 100 via an anisotropic condactive film (ACF) 130 in mounting the driving IC, a pressure (indicated by an arrow in FIG. 13) is applied to the wiring board 100. This pressure may act on a section between a pad 109 and a metal wire 101 and cause the pad 109 to come in contact with the metal wire 101, which may cause a leak failure. The contact between the pad 109 and the metal wire 101 is likely to occur in a region (short region RS1 in FIG. 13) where the pad 109 and the metal wire 101 are closest to each other.

Further, as illustrated in FIG. 13, the above leak failure is more likely to occur especially in a case where the driving IC is misaligned when mounted, and the bump 120 is thereby displaced relative to the pad 109.

(Narrower Pitch)

In a case where, for preventing the occurrence of the above leak failure, a distance between the pad 109 and the metal wire 101 is increased (i.e., a space between the pad 109 and the metal wire 101 in the region RS illustrated in FIG. 13 is widened), a narrower pitch of the pads 109 is problematically precluded.

The present invention has been accomplished in the view of the above problems. An object of the present invention is to provide a wiring board and a liquid crystal display device, each of which makes a leak failure difficult to occur and also makes it possible to have a narrower pad pitch.

In order to solve the above problems, a wiring board of the present invention includes: a substrate; pads provided in a plurality of rows on the substrate; and connecting lines formed on the substrate and each connected to one of the pads, the pads arranged in the plurality of rows including: first-row pads connected to first connecting lines; and second-row pads connected to second connecting lines, the first connecting lines being longer than the second connecting lines, each of the first connecting lines being formed so as to be separated from a corresponding one of the second-row pads by at least an insulating layer, and so as to extend not through a region between the corresponding second-row pad and a second-row pad adjacent to the corresponding second-row pad, but through a lower region below the corresponding second-row pad.

According to the above arrangement, among the pads arranged in a plurality of rows, the first connecting lines are connected to respective corresponding first-row pads while none of the first connecting lines are provided between second-row pads adjacent to each other.

The following describes an example case where the wiring board is used as a glass substrate for a liquid crystal display device. This glass substrate has metal wires and the like formed thereon. Suppose, for example, that thin film transistors (TFTs) formed on a center section of the glass substrate for a liquid crystal display device need to be connected to, e.g., a driving IC having bumps arranged in a plurality of rows. In this case, first-row pads among pads to which the driving IC is to be mounted are each connected to a wire drawn from one of the TFTs while a widthwise center of each connecting line is not provided between second-row pads adjacent to each other.

The wiring board of the present invention thus can prevent a leak failure occurring due to the contact between a pad and a connecting line.

Specifically, regarding the contact between a pad and a connecting line, in a case where each first connecting line is formed between pads adjacent to each other and a distance between each of such pads and the connecting line is arranged to be small for attaining a narrower pitch, the pad is likely to come into contact with the connecting line in a region where the distance is small. In addition, in a case where an electronic component or the like is mounted to pads, or especially in a case where such an electronic component is mounted to pads in a misaligned manner, the above contact is likely to occur due to a force applied so as to press the pads against the substrate.

In view of this, according to the wiring board of the present invention, no connecting line is formed between pads adjacent to each other. This reduces the risk of the above leak failure occurring due to the contact between a pad and a connecting line.

In addition, the wiring board of the present invention makes it possible to achieve a narrower pad pitch as well.

According to the above arrangement, each first connecting line is provided through a lower region below a pad. This eliminates the need to provide a connecting line between second-row pads. Thus, even in a case where a distance between second-row pads adjacent to each other is reduced, the contact between either of such second-row pads and a connecting line is not likely to occur. This allows a narrower pitch to be achieved.

This makes it possible to attain, by using the wiring board having the above arrangement, a wiring board capable of reducing the risk of the occurrence of a leak failure and also achieving a narrower pad pitch at the same time.

The wiring board of the present invention may be arranged so that each of the second-row pads is formed by increasing a line width of a corresponding one of the second connecting lines.

According to the above arrangement, each second-row pad is formed by increasing a line width of a connecting line. This allows the second-row pads to be each formed by a simple method in a region that overlaps with a connecting line connected to a corresponding first-row pad.

The wiring board of the present invention may preferably be arranged so that the second-row pads are softer than the first connecting lines.

The wiring board of the present invention may be arranged so that the second-row pads are made of aluminum; and the first connecting lines are made of any one of titanium, titanium nitride, an alloy of titanium and titanium nitride, tantalum, tantalum nitride, and an alloy of tantalum and tantalum nitride.

The wiring board of the present invention may be arranged so that the second-row pads are made of aluminum or titanium; and the first connecting lines are made of nickel.

According to the above arrangement, the pads in an upper layer are softer than the connecting lines in a lower layer. This further reduces the risk of a leak failure occurring due to the contact between a pad and a connecting line in a region where the pad overlaps with the connecting line.

Specifically, the above contact between a pad and a connecting line with which the pad overlaps occurs in mounting an electronic component such as a driving IC to the pads, due to, e.g., a pressing force applied in a direction toward the substrate (i.e., direction perpendicular to the substrate; direction from the pad to the substrate) from the pad to the connecting line with which the pad overlaps.

In regard to this, according to the above arrangement, the pads in the upper layer are softer than the connecting lines in the lower layer. This allows the above force to be relaxed (stress relaxation) by the pads in the upper layer, thereby reducing the risk of the above contact between a pad and a connecting line with which the pad overlaps.

As a result, the above arrangement prevents the occurrence of a leak failure caused by the contact between a pad and a connecting line with which the pad overlaps.

The wiring board of the present invention may be arranged so that the substrate is a display device substrate.

The wiring board of the present invention may be arranged so that the display device substrate is a glass substrate for a liquid crystal display device.

The above arrangement makes it possible to use the wiring board including the pads and the connecting lines as a display device substrate for, e.g., an electro luminescence (EL) display device or a liquid crystal display device.

This allows for a reduction of a connection region of a display device substrate. As a result, the display device substrate can be downsized by, e.g., reducing a size of a frame of a display device substrate.

The wiring board of the present invention may preferably be arranged so that the substrate is a printed wiring board.

According to the above arrangement, the wiring board is used as a printed wiring board (board for a printed wiring). This allows for, e.g., downsizing of a printed wiring board.

In order to solve the above problems, a liquid crystal display device of the present invention includes: a wiring board including: a substrate; pads provided in a plurality of rows on the substrate; and connecting lines formed on the substrate and each connected to one of the pads; and an electronic component mounted on a corresponding pad included in the wiring board, the wiring board being a glass substrate for the liquid crystal display device, the pads arranged in the plurality of rows including: first-row pads connected to first connecting lines; and second-row pads connected to second connecting lines, the first connecting lines being longer than the second connecting lines, each of the first connecting lines being formed so as to be separated from a corresponding one of the second-row pads by at least an insulating layer, and so as to extend not through a region between the corresponding second-row pad and a second-row pad adjacent to the corresponding second-row pad, but through a lower region below the corresponding second-row pad.

The above arrangement achieves a narrower pitch of pads provided on a glass substrate for a liquid crystal display device. This in turn allows for, e.g., reduction in size of a frame of the glass substrate or reduction in weight and thickness of, e.g., a liquid crystal display device including a glass substrate for a liquid crystal display device, the glass substrate having electronic components mounted directly thereon (chip on glass; COG).

In addition, the above arrangement reduces the risk of the occurrence of a leak failure. This enables higher-yield production of liquid crystal display devices. Furthermore, in consequence, such liquid crystal display devices thus produced have higher reliability.

The liquid crystal display device of the present invention may be arranged so that the electronic component is mounted directly on the corresponding pad included in the wiring board so as to be connected to the glass substrate for a liquid crystal display device by chip-on-glass connection.

According to the chip-on-glass connection, chip components as electronic components are mounted directly to pads provided on the glass substrate. Thus, stress relaxation is unlikely to occur and an insulating layer on a surface of the board is likely to be broken.

In view of this, according to the above arrangement, each first connecting line is provided not in a region between second-row pads adjacent to each other, but in a lower region below a corresponding second-row pad. Thus, even if misalignment occurs when, for example, a chip component is mounted, the liquid crystal display device prevents a leak failure from occurring between the chip component and a connecting line.

As described above, each of the wiring board and the liquid crystal display device of the present invention is arranged so that the pads arranged in the plurality of rows includes: first-row pads connected to first connecting lines; and second-row pads connected to second connecting lines, the first connecting lines being longer than the second connecting lines, and that each of the first connecting lines being formed so as to be separated from a corresponding one of the second-row pads by at least an insulating layer, and so as to extend not through a region between the corresponding second-row pad and a second-row pad adjacent to the corresponding second-row pad, but through a lower region below the corresponding second-row pad.

This allows for production of a wiring board and a liquid crystal display device, each of which has a reduced risk of a leak failure and achieves a narrower pad pitch.

### BRIEF DESCRIPTION OF DRAWINGS

FIG. 1 is a view illustrating wiring of a wiring board according to an embodiment of the present invention.

FIG. 2 is a view schematically illustrating a cross section taken along line A-A of FIG. 1.

FIG. 3 is a view schematically illustrating a cross section taken along line B-B of FIG. 1.

FIG. 4 is a view schematically illustrating a cross section taken along line C-C of FIG.

FIG. 5 is a view schematically illustrating a cross section taken along line D-D of FIG. 1.

FIG. 6 is a view schematically illustrating a cross section taken along line D-D of FIG. 1 according to another embodiment of the present invention.

FIG. 7 is a view schematically illustrating a cross section taken along line E-E of FIG. 1.

FIG. 8 is a view schematically illustrating a cross section taken along line F-F of FIG. 1.

FIG. 9 is a view schematically illustrating a cross section taken along line F-F of FIG. 1 according to another embodiment of the present invention.

FIG. 10 is a view schematically illustrating a cross section taken along line F-F of FIG. 1 according to still another embodiment of the present invention.

FIG. 11 is a view illustrating a configuration of a wiring board disclosed in Patent Literature 1.

FIG. 12 is a cross-sectional view taken along line H-H of FIG. 15.

FIG. 13 is a view illustrating a condition where an IC misaligned is being mounted to a wiring board.

FIG. 14 is a view illustrating wiring of a wiring board according to a conventional technique.

FIG. 15 is a view schematically illustrating a cross section taken along line I-I of FIG. 14.

FIG. 16 is a view schematically illustrating a cross section taken along line J-J of FIG. 14.

FIG. 17 is a view schematically illustrating a cross section taken along line K-K of FIG. 14.

FIG. 18 is a view schematically illustrating a cross section taken along line L-L of FIG. 14.

FIG. 19 is a view illustrating a configuration of a liquid crystal panel disclosed in Patent Literature 2.

FIG. 20 is a view illustrating a configuration of a bottom surface of a driving IC shown in FIG. 19.

FIG. 21 is a view illustrating the liquid crystal display panel on which the driving IC shown in FIG. 20 is mounted.

FIG. 22 is a view schematically illustrating an arrangement of a liquid crystal display device according to an embodiment of the present invention.

### REFERENCE SIGNS LIST

1 wiring board
2 wiring board
5 substrate
10 metal wire (connecting line)
10a first metal wire
10b second metal wire
20a first insulating layer
20b second insulating layer
25 insulating layer
30 pad
30a first-row pad
30b second-row pad
32 pad electrode
35 pad opening
40 connecting metal section
100 wiring board
101 metal wire
102 interlayer insulating layer
103 through hole
105 pad
106 interlayer insulating layer
107 pad through hole
109 pad
110 insulating layer
120 bump
130 ACF 200 liquid crystal display device
210 frame
220 liquid crystal panel
230 electronic component
240 backlight unit
300 liquid crystal panel
310 input line
320 electrode pad
400 driving IC
410 bump
X drawing region
Y second connection region
Z first connection region
PD pad region
RS short region

### DESCRIPTION OF EMBODIMENTS

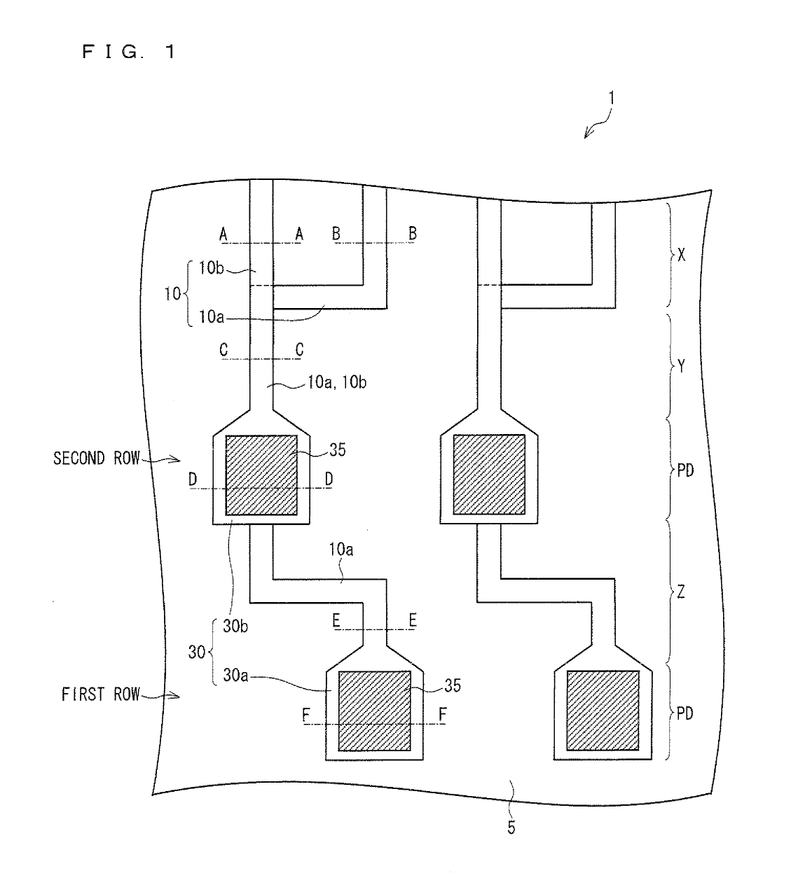

One embodiment of the present invention is described below with reference to FIGS. 1 to 10. The following description compares the present invention with a conventional wiring board so as to clarify features of the present invention.

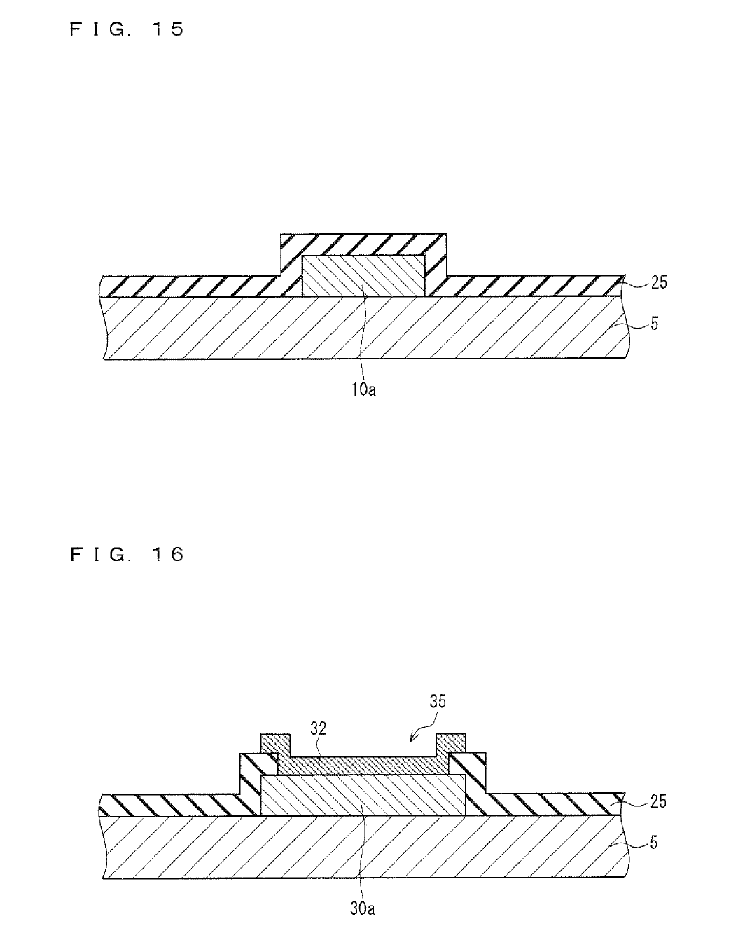

FIG. 1 is a view illustrating wiring of a wiring board 1 of the present embodiment. FIG. 14 is a view illustrating wiring of a conventional wiring board 2 which has the same number of pads 30 as those of the wiring board 1.

(Overall Arrangement)

As illustrated in FIG. 1, the wiring board 1 of the present embodiment includes a substrate 5 provided with pads 30 each serving as an electrical contact with an electronic component such as an integrated circuit (IC); metal wires 10 each serving as a connecting line and connected to a corresponding pad 30; and insulating layers (not shown) used, e.g., to isolate the pads 30 from the metal wires 10.

Each of the pads 30 has a section where the insulating layer is not provided so as to allow electrical connection with an electronic component. In other words, the insulating layers have respective sections at each of which an opening is formed. Such sections each correspond to a pad opening 35.

(Pads)

The pads 30 on the wiring board 1 are provided in a plurality of rows, specifically in a staggered configuration. More specifically, the pads 30 are provided on the substrate 5 in two rows (“FIRST ROW” and “SECOND ROW” shown in FIG. 1). Further, respective pads 30 (first-row pads 30a forming a first row) in the first row have a pad pitch identical to a pad pitch of respective pads 30 (second-row pads 30b forming a second row) in the second row. Each pad 30a in the first row is shifted by a half of a pad pitch relative to a corresponding one of the pads 30b in the second row, and vice versa.

Such a configuration of the pads 30 is also applied in the conventional wiring board 2 illustrated in FIG. 14. Specifically, as illustrated in FIG. 14, pads 30 are arranged in first and second rows, and respective pads 30 in the first row are shifted relative to those in the second row so as to form a staggered configuration.

(Wiring)

The following describes how the pads 30 are wired.

As illustrated in FIG. 14, the conventional wiring board 2 includes wires each of which is connected to a first-row pad 30 and extends between second row pads 30b.

In contrast, according to the wiring board 1 of the present embodiment, as illustrated in FIG. 1., the first-row pads 30a are wired so that each of the first-row pads 30a is connected to a metal wire 10 (first metal wire 10a) which is a line connected to a first-row pad 30a and which extends through a lower region below a corresponding second-row pad 30b. In other words, none of the wires (first metal wires 10a) connected to the first-row pads 30a extends between second-row pads 30b.

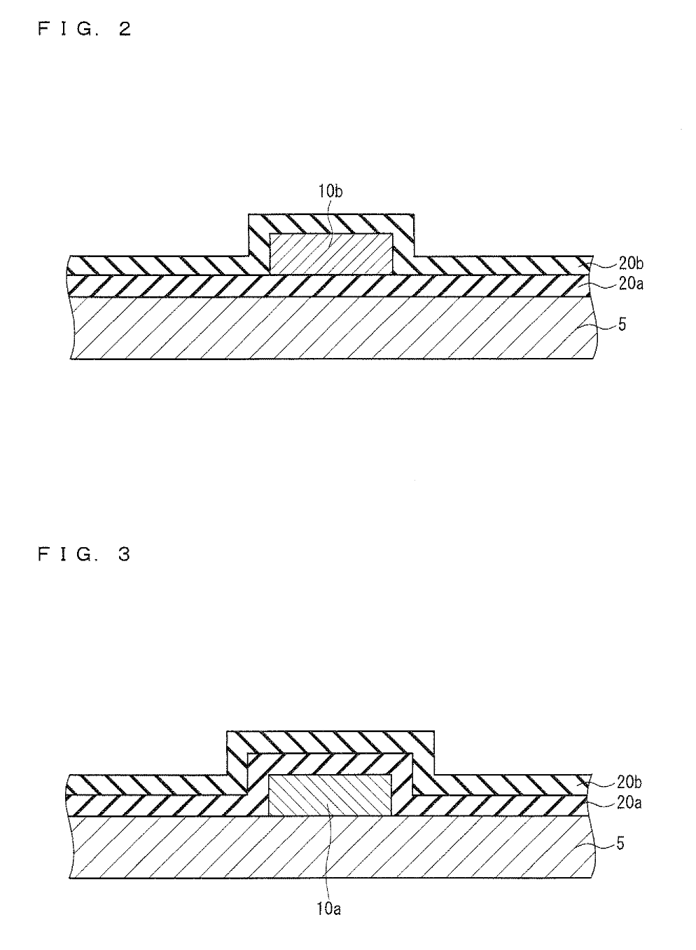

The following describes a specific wiring method with reference to cross-sectional views (FIGS. 2 through 10 and FIGS. 15 through 18) of the wiring boards 1 and 2.

(Conventional)

According to the conventional wiring board 2, as illustrated in FIG. 14, first metal wires 10a each connected to a first-row pad 30a and second metal wires 10b each connected to a second-row pad 30b are provided in a single layer on the substrate 5 so as to extend from a drawing region (region X illustrated in FIG. 14) through to the pads 30 (first-row pads 30a and second-row pads 30b; pad regions PD illustrated in FIG. 14). Further, the first and second metal wires 10a and 10b are covered with a single insulating layer (not shown), except for regions requiring no insulation, such as regions via which the first and second metal wires are connected to other components.

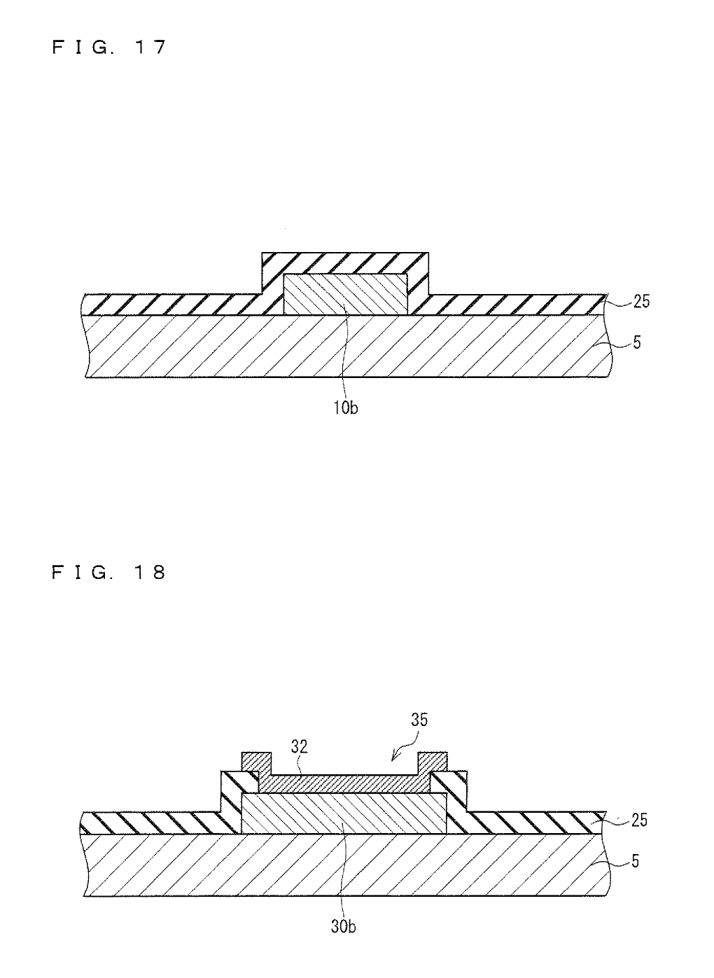

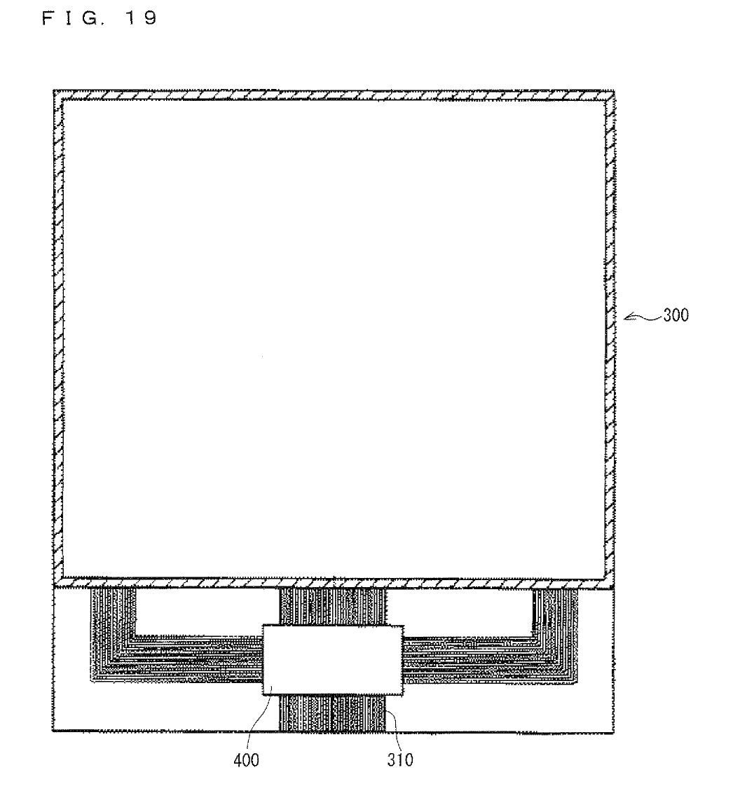

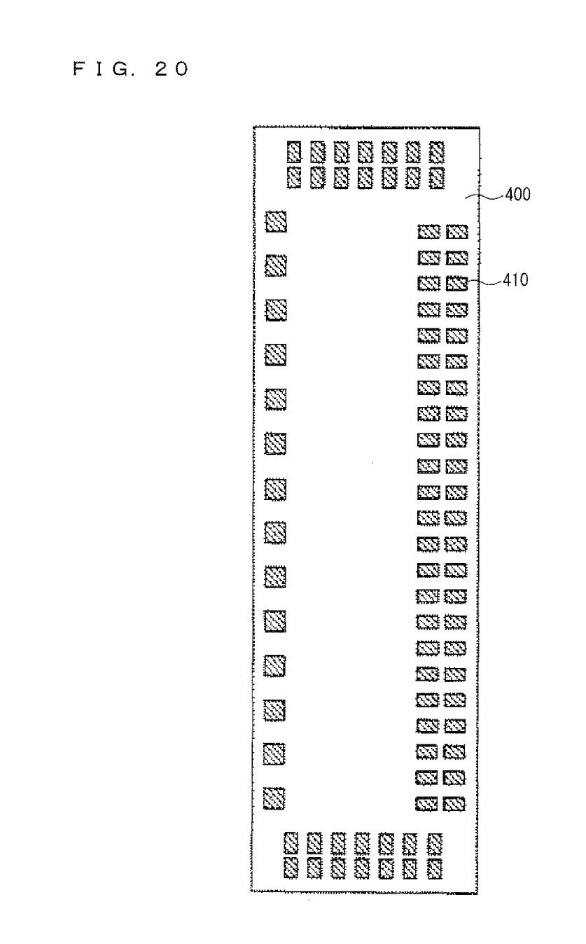

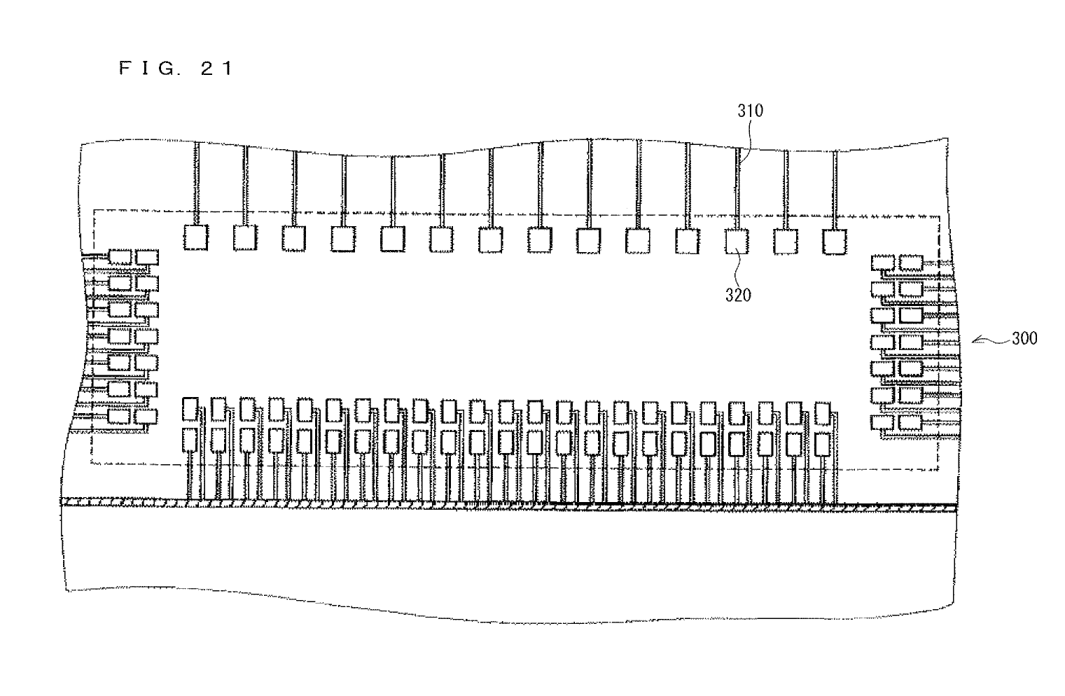

More specifically, as illustrated in FIGS. 15 and 17, the conventional wiring board 2 includes first and second metal wires 10a and 10b which are provided in a single layer on the substrate 5 and which are made of an identical material. Further, the first and second metal wires 10a and 10b do not overlap with each other, and are covered with a single insulating layer 25.

FIG. 15 is a cross-sectional view (taken along line I-I of FIG. 14) of a first metal wire 10a in the drawing region X. FIG. 17 is a cross-sectional view (taken along line K-K of FIG. 14) of a second metal wire 10b in the drawing region X.

### Present Embodiment

In contrast, according to the wiring board 1 of the present embodiment, each first metal wire 10a connected to a first-row pad 30a does not overlap, on the substrate 5, with a corresponding second metal wire 10b connected to a second-row pad 30b in a drawing region (region X illustrated in FIG. 1), but does overlap with the second metal wire 10b in a second connection region (region Y illustrated in FIG. 1), in which the second metal wires 10b are connected to the corresponding second-row pads 30b.

Specifically, as illustrated in FIGS. 2 and 3, each first metal wire 10a and a corresponding second metal wire 10b are formed in different positions on the substrate 5 in the drawing region X so as not to overlap with each other. The first metal wire 10a is covered with first and second insulating layers 20a and 20b, whereas the second metal wire 10b is covered with the second insulating layer 20b.

The first insulating layer 20a is provided between the second metal wire 10b and the substrate 5.

This results from forming the first metal wire 10a, the first insulating layer 20a, the second metal wire 10b, and the second insulating layer 20b in this order on the substrate 5.

As described below, the first metal wires 10a are made of a material different from a material of which the second metal wires 10b are made.

FIG. 2 is a cross-sectional view (taken along line A-A of FIG. 1) of a second metal wire 10b in the drawing region X. FIG. 3 is a cross-sectional view (taken along line B-B of FIG. 1) of a first metal wire 10b in the drawing region X.

The first metal wire 10a then overlaps with the second metal wire 10b in a thickness direction of the substrate 5, i.e., in a direction perpendicular to the substrate 5, before the first metal wire 10a reaches a point at which the second metal wire 10b is connected to a corresponding second-row pad 30b.

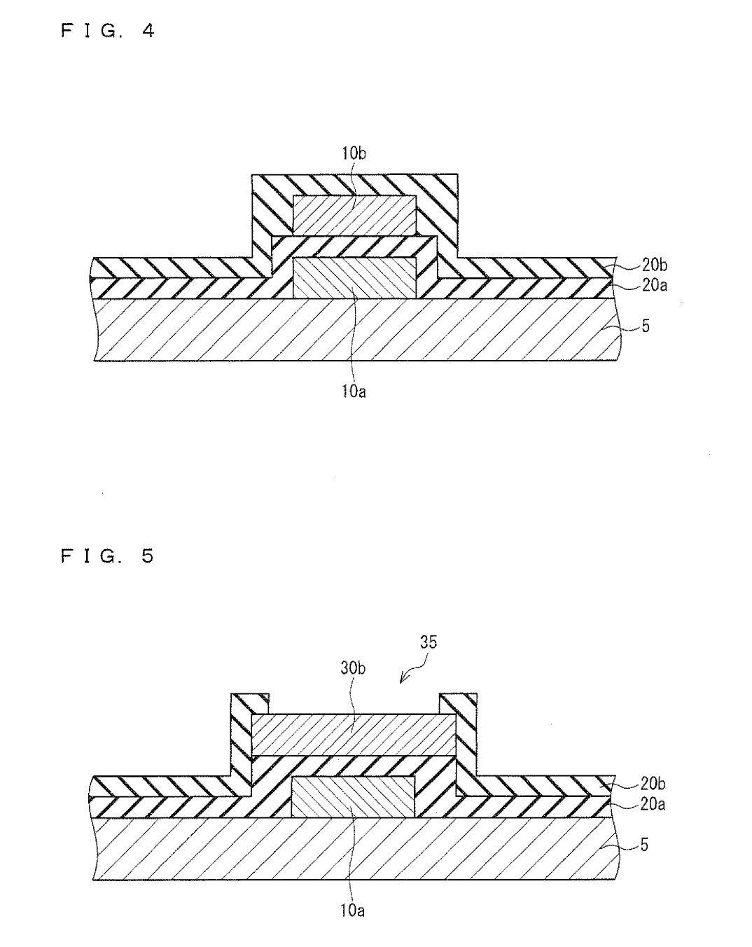

Specifically, as illustrated in FIG. 4, in the second connection region Y, the second metal wire 10b is in a layer above the first metal wire 10a. More specifically, the first with the first insulating layer 20a in the same manner as shown in the cross section of FIG. 3. Further, the second metal wire 10b is provided in a layer above the first insulating layer 20a and is covered with the second insulating layer 20b.

FIG. 4 is a view (cross-sectional view taken along line C-C of FIG. 1) illustrating respective cross sections of the first and second metal wires 10a and 10b in the second connection region Y.

(Second-Row Pads)

The following describes the pads 30 in the second row. The pads 30 in the second row, i.e., second-row pads 30b, of the wiring board 1 according to the present embodiment are each formed by increasing a width of a second metal wire 10b and forming a corresponding opening in the second insulating layer 20b.

This is explained specifically by using a cross section of a section where a second-row pad 30b is formed. As shown in FIG. 5, each second-row pad 30b is formed by increasing a line width of a second metal wire 10b included in the layered configuration present in the second connection region Y illustrated in FIG. 4.

Further, an opening is formed at a section in the second insulating layer 20b covering the second metal wire 10b in FIG. 4, thereby forming a pad opening 35 in a layer above the second-row pad 30b.

Specifically, each second-row pad 30b of the present embodiment is provided in a section on an extended line of a second metal wire 10b. In this section, a width of the second metal wire 10b is increased and the insulating layer as a surface layer is removed, for allowing electrical connection with, e.g., an electronic component (see the region PD in FIG. 1).

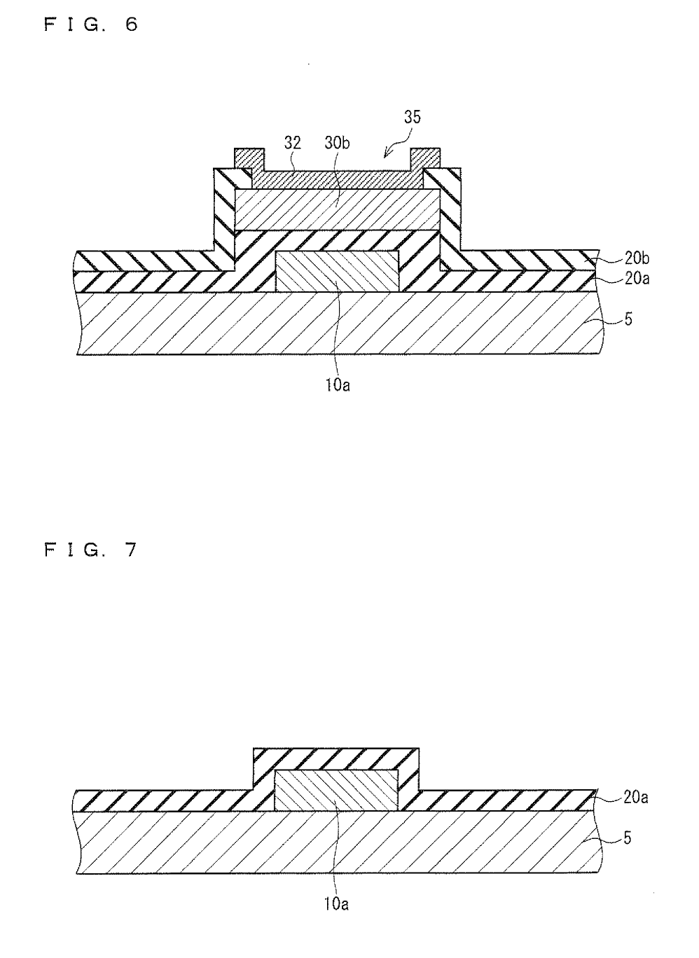

Note that the pads 30 in the second row are not necessarily arranged as above. For example, as illustrated in FIG. 6, each second-row pad 30b, formed by increasing a width of a second metal wire 10b, may be provided with a pad electrode 32 made of, e.g., indium tin oxide (ITO) and formed in a layer above the second-row pad 30b. For example, formation of the pad electrode 32 of a metal material different from a metal material of which the second metal wire 10b is made allows for, e.g., improvement in stability of connection with electronic components.

FIG. 5 is a cross-sectional view (taken along line D-D of FIG. 1) of a pad 30 in the second row. FIG. 6 is a cross-sectional view illustrating another arrangement of a pad 30 in the second row.

The above arrangement is contrasted with the conventional wiring board 2. As illustrated in FIG. 18 which is a cross-sectional view taken along line L-L of FIG. 14, each second metal wire 10b has a line width increased so that a second-row pad 30b is provided. Further, the insulating layer 25 is caused to have a corresponding opening, so that a pad opening 35 is formed. Each second-row pad 30b is normally provided with a pad electrode 32 made of ITO and formed in a layer above the second-row pad 30b.

(First-Row Pads)

The following describes the first metal wires 10a and the first-row pads 30a.

As described above, according to the wiring board 1 of the present embodiment, each first metal wire 10a is drawn from a layer below a corresponding second-row pad 30b to a first connection region (region Z illustrated in FIG. 1) before the first metal wire 10a reaches a point at which the first metal wire 10a is connected to a corresponding first-row pad 30a. In other words, the drawing region X is electrically connected to the first connection region Z while no wire is disposed between second-row pads 30b.

Each first metal wire 10a is drawn to the first connection region Z. The first metal wire 10a is bent so as to be capable of being connected to a corresponding one of the first-row pads 30a whose positions are shifted relative to the respective second-row pads 30b in the staggered configuration. Each first metal wire 10b is then connected to a corresponding first-row pad 30a.

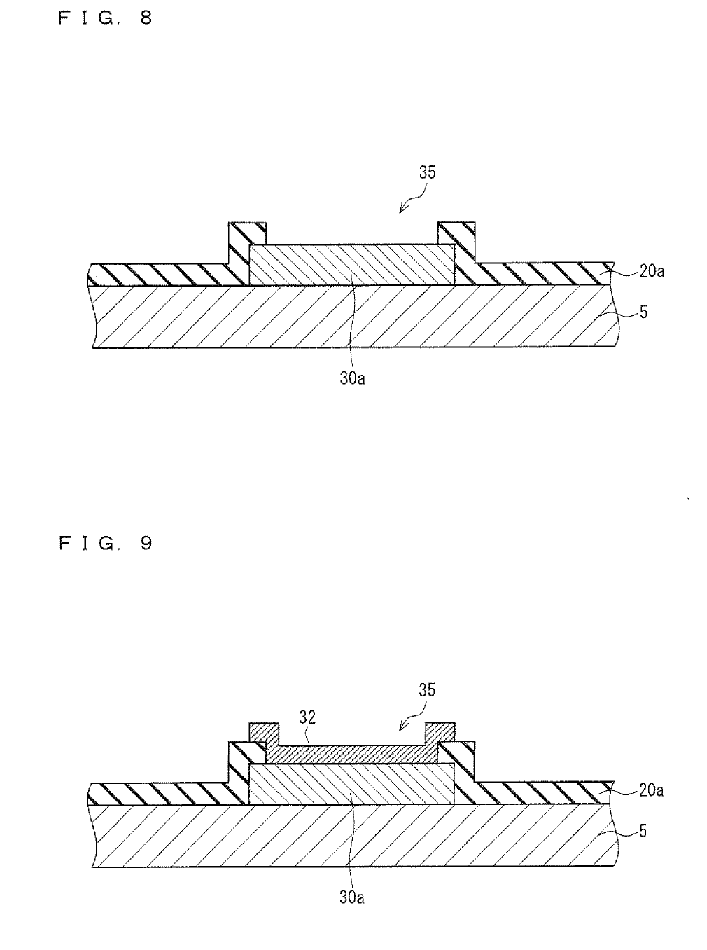

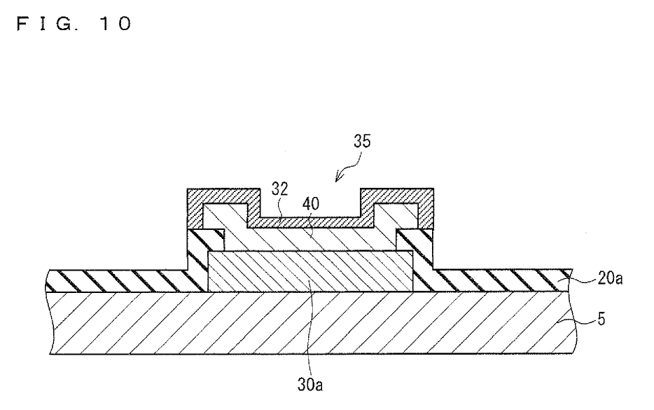

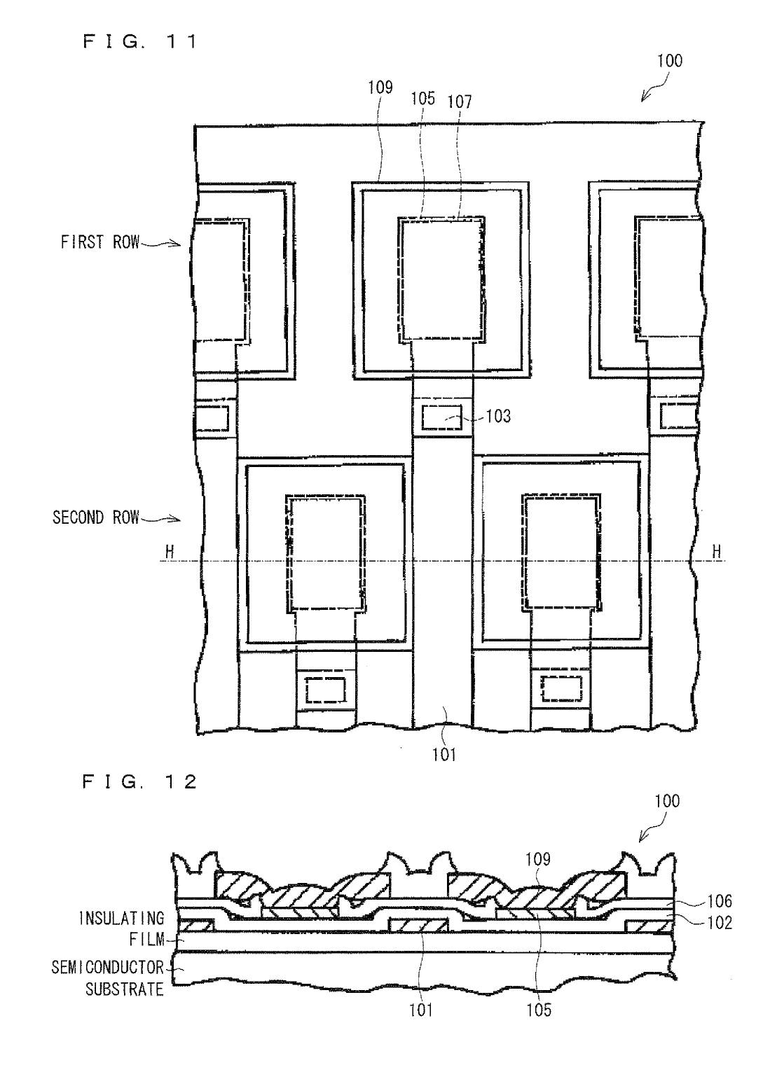

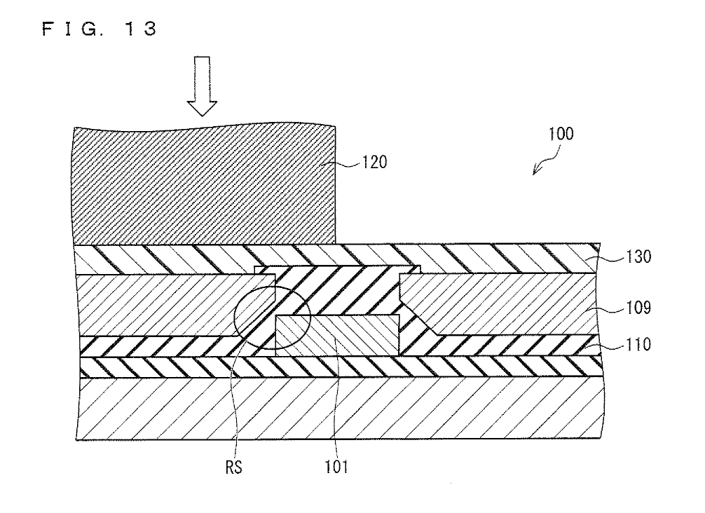

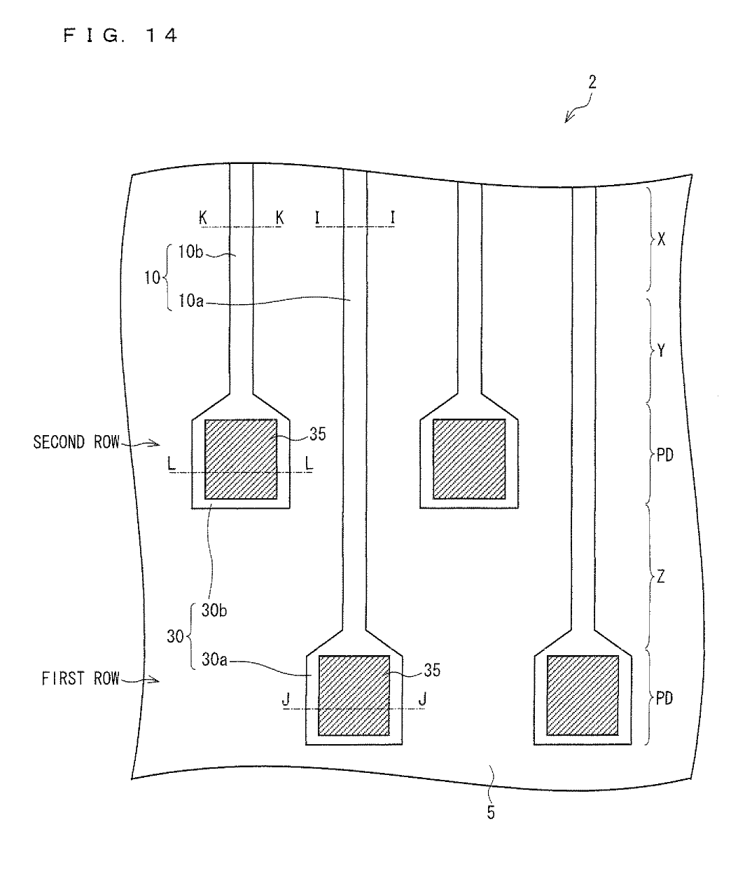

The following describes this in detail with reference to cross-sectional views. Both FIGS. 7 and 8 illustrate the wiring board 1 of the present embodiment. FIG. 7 is a cross-sectional view (taken along line E-E of FIG. 1) of a first metal wire 10a in the first connection region Z. FIG. 8 is a cross-sectional view (taken along line F-F of FIG. 1) of a first-row pad 30a. FIG. 9 is a cross-sectional view illustrating another arrangement of a pad 30 in the first row.

As illustrated in FIG. 7, in the first connection region Z, no second metal wire 10b is provided in a layer above the first metal wire 10a. This is because each second metal wire 10b is connected to its corresponding second-row pad 30b and does not extend beyond the connection.

FIG. 7 illustrates an arrangement in which the first metal wire 10a is covered only with the first insulating layer 20a. However, as illustrated in FIG. 3, the first metal wire 10a may, for example, be covered with the first and second insulating layers 20a and 20b.

As illustrated in FIG. 8, each first metal wire 10a is again caused to have a line width increased in the pad region PD corresponding to the first row, thereby forming a first-row pad 30a. Further, an opening is formed at a section of the first insulating layer 20a in a layer above the first-row pad 30a, thereby forming a pad opening 35. In addition, as illustrated in FIG. 9, each first-row pad 30a may be provided with a pad electrode 32 made of, e.g., ITO and formed in the layer above the first-row pad 30a. The above arrangement is similar to the equivalent of the second-row pads 30b described above.

The pads 30 in the first row of the conventional wiring board 2 are arranged similarly to those of the wiring board 1 of the present invention. Specifically, as illustrated in FIG. 16, each first-row pad 30a of the conventional wiring board 2 is also formed by increasing a width of a first metal wire 10a and an opening is formed at a section in the insulating layer 25 in the layer above the first metal wire 10a, as in the first-row pads 30a of the present embodiment. In addition, each first-row pad 30a is normally provided with a pad electrode 32 in a layer above the first-row pad 30a. Note that FIG. 16 is a cross-sectional view (taken along line J-J of FIG. 14) of a first-row pad 30a of the conventional wiring board 2.

As described above, the wiring board 1 of the present embodiment makes it possible to ensure an electrical continuity to each first-row pad 30a while disposing no wire connected to a first-row pad 30a between second-row pads 30b adjacent to each other. Thus, particularly even in a case where misalignment occurs in mounting, a leak failure is unlikely to occur. The wiring board also achieves a narrower pad pitch at the same time.

Since no wire is provided between second-row pads 30b, an electrical short circuit is unlikely to occur between a second-row pad 30b and a first metal wire 10a even in a case where, e.g., misalignment occurs when a driving IC is mounted to the wiring board 1. This consequently prevents the occurrence of a leak failure.

The above effect is significant in a case where the wiring board 1 of the present embodiment is used for a chip-on-glass connection. The chip-on-glass (COG) connection refers to a connection in which a component such as a semiconductor chip is mounted directly to a glass substrate.

One specific example is a case where the wiring board 1 is used as a glass substrate for a liquid crystal display device and a chip component such as a driving IC is mounted directly to the glass substrate for a liquid crystal display device.

According to the chip-on-glass connection, the chip component is mounted directly to pads provided on the glass substrate. Thus, interlayer stress relaxation is unlikely to occur, and the above insulating layer tends to be broken. This indicates that, for example, misalignment caused in mounting is especially likely to result in a leak failure between a pad and a connecting line.

In view of this, the wiring board 1 of the present embodiment includes no wire between pads. This prevents the occurrence of the above leak failure.

The absence of the need to provide a wire between second-row pads 30b makes it possible to have a narrower distance between such second-row pads 30b. This in turn achieves a narrower pitch of the pads 30.

The above description deals with the arrangement in which each first-row pad 30a is formed by increasing a width of a first metal wire 10a, whereas each second-row pad 30b is formed by increasing a width of a second metal wire 10b. However, respective arrangements of the pads 30 of the present invention are not limitedly arranged as above.

For example, the first-row pads 30a may be made of a material different from a material of which the first metal wires 10a are made, or may each be formed in a layer different from a corresponding first metal wire 10a. Similarly, the second-row pads 30b may be made of a material different from a material of which the second metal wires 10b are made, or may each be formed in a layer different from its corresponding second metal wire 10b.

The above description deals with the arrangement of the pads 30 in the first row with reference to FIG. 8. In the arrangement, the first-row pads 30a are formed in a layer in which the first metal wires 10a are formed, by increasing a width of each first metal wire 10a. However, the pads 30 in the first row of the present invention are not limitedly arranged as above.

For example, as illustrated in FIG. 10, each first-row pad 30a formed by increasing a width of a first metal wire 10a may additionally be provided with a connecting metal section 40 which is made of, e.g., a material similar to a material of which the second metal wires 10b are made and which is formed in a layer above the first-row pad 30a. Further, according to need, the connecting metal section 40 may be provided with a pad electrode 32, as described above, formed in a layer above the connecting metal section 40.

This arrangement reduces a height difference between the pads 30 in the first row and those in the second row. This in turn enables more reliable mounting.

(Metal Materials)

The following describes metal materials used to form the metal wires (first and second metal wires 10a and 10b) and the pads (first-row and second-row pads 30a and 30b).

As described above with reference to FIG. 5, each first metal wire 10a of the wiring board 1 according to the present embodiment extends through a layer below a corresponding second-row pad 30b.

In the present embodiment, the second-row pads 30b are preferably made of a material different from a material of which the first metal wires 10a are made.

According to the present embodiment, each second-row pad 30b is formed by increasing a line width of a second metal wire 10b on an extended line of the second metal wire 10b. Thus, the second-row pads 30b and the second metal wires 10b are made of an identical metal material.

TABLE 1

| | Combination | Combination | Combination | Combination |
|---|---|---|---|---|
| | 1 | 2 | 3 | 4 |
| Second-row | Al | Al | Al | Ti |
| pad | | | | |
| First metal | Ti/TiN | Ta/TaN | Ni | Ni |
| wire | | | | |
| First and | SiN, SiO₂ | SiN, SiO₂ | SiN, SiO₂ | SiN, SiO₂ |
| second | | | | |
| insulating | | | | |
| layers | | | | |

Table 1 shows respective materials of (i) the second-row pads 30, (ii) the first metal wires 10a, and (iii) the first and second insulating layers 20a and 20b.

As shown in Table 1, according to the wiring board 1 of the present embodiment, the material of the second-row pads 30b is softer than that of the first metal wires 10a.

Specifically, in general, the order of hardness of metals (on the Mohs hardness scale) is Ni>Ti>Al. Thus, for example, the material of the second-row pads 30b is softer than that of the first metal wires 10a in a case of Combination 1 in Table 1, where the second-row pads 30b are made of Al (aluminum) and the first metal wires 10a are made of an alloy of Ti (titanium) and TIN (titanium nitride).

The material of the second-row pads 30b is softer than that of the first metal wires 10a in the case of any other Combination 2, 3, or 4 as well.

According to this arrangement, in mounting, each second-row pad 30b in an upper layer is made of a material softer than a material of a corresponding first metal wire 10a in a lower layer. This reduces the risk of any second-row pad 30b coming into contact with a first metal wire 10a in a layer below the second-row pad 30b, thereby reducing the risk of the occurrence of a leak failure.

Specifically, an IC or the like is mounted to second-row pads 30b, with a force applied from, e.g., each bump of the IC to a layered body of a corresponding second-row pad 30b and a first metal wire 10a so as to press the layered body toward the substrate 5.

The above force may cause the second-row pad 30b in the upper layer to come into contact with the first metal wire 10a in the lower layer. In view of this, in the above arrangement, the second-row pads 30b in the upper layer are softer than the first metal wires 10a in the lower layer. Thus, the above force is relaxed (stress relaxation) by the second-row pads 30b in the upper layer. As a result, the second-row pads 30b are unlikely to come into contact with the respective first metal wires.

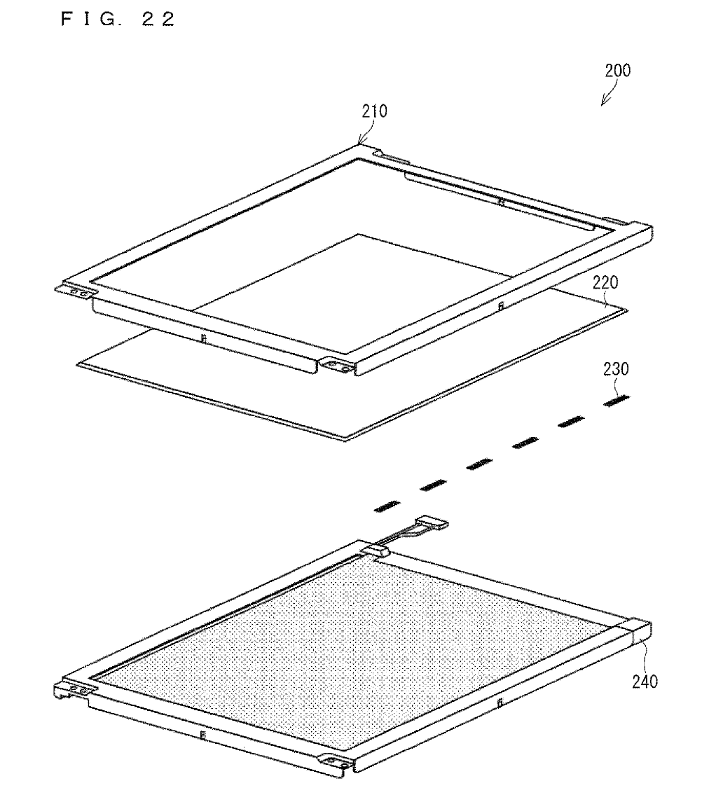

The wiring board of the present invention is applicable to various electronic devices; for example, it is suitably applicable to a liquid crystal display device. FIG. 22 is a view schematically illustrating an arrangement of a liquid crystal display device 200 including the wiring board of the present invention.

As illustrated in FIG. 22, the liquid crystal display device 200 includes: a frame 210; a liquid crystal panel 220; electronic components 230 provided to the liquid crystal panel 220; and a backlight unit 240. For example, the wiring board of the present invention is applicable to a glass substrate for liquid crystal display device, the glass substrate constituting the liquid crystal panel 220.

The present invention is not limited to the description of the embodiment above, but may be altered by a skilled person within the scope of the claims. An embodiment based on any combination of technical means properly modified within the scope of the claims is also encompassed in the technical scope of the present invention.

### INDUSTRIAL APPLICABILITY

The wiring board of the present invention achieves a narrower pad pitch, and is therefore suitable for applications requiring high-density mounting.

1. A wiring board comprising:
a substrate;
pads provided in a plurality of rows on the substrate; and
connecting lines formed on the substrate and each connected to one of the pads,
the pads arranged in the plurality of rows including:
first-row pads connected to first connecting lines; and
second-row pads connected to second connecting lines,
the first connecting lines being longer than the second connecting lines,
each of the first connecting lines being formed so as to be separated from a corresponding one of the second-row pads by at least an insulating layer, and so as to extend not through a region between the corresponding second-row pad and a second-row pad adjacent to the corresponding second-row pad, but through a lower region below the corresponding second-row pad.

2. The wiring board according to claim 1, wherein each of the second-row pads is formed by increasing a line width of a corresponding one of the second connecting lines.

3. The wiring board according to claim 1, wherein the second-row pads are softer than the first connecting tines.

4. The wiring board according to claim 3, wherein:
the second-row pads are made of aluminum; and
the first connecting lines are made of any one of titanium, titanium nitride, an alloy of titanium and titanium nitride, tantalum, tantalum nitride, and an alloy of tantalum and tantalum nitride.

5. The wiring board according to claim 3, wherein:
the second-row pads are made of aluminum or titanium; and
the first connecting lines are made of nickel.

6. The wiring board according to claim 1, wherein the substrate is a display device substrate.

7. The wiring board according to claim 6, wherein the display device substrate is a glass substrate for a liquid crystal display device.

8. The wiring hoard according to claim 1, wherein the substrate is a printed wiring board.

9. A liquid crystal display device comprising:
a wiring board including:
a substrate;
pads provided in a plurality of rows on the substrate; and
connecting lines formed on the substrate and each connected to one of the pads; and
an electronic component mounted on a corresponding pad included in the wiring board,
the wiring board being a glass substrate for the liquid crystal display device,
the pads arranged in the plurality of rows including:
first-row pads connected to first connecting lines; and
second-row pads connected to second connecting lines,
the first connecting lines being longer than the second connecting lines,
each of the first connecting lines being formed so as to be separated from a corresponding one of the second-row pads by at least an insulating layer, and so as to extend not through a region between the corresponding second-row pad and a second-row pad adjacent to the corresponding second-row pad, but through a lower region below the corresponding second-row pad.

10. The liquid crystal display device according to claim 9, wherein the electronic component is mounted directly on the corresponding pad included in the wiring board so as to be connected to the glass substrate for a liquid crystal display device by chip-on-glass connection.
